(19) United States
(12) Patent Application Publication
(10) Pub. No.: US 2014/0312909 A1
(43) Pub. Date: Oct. 23, 2014

(54) PROGRAMMABLE CONTACT INPUT APPARATUS AND METHOD OF OPERATING THE SAME

(71) Applicant: GE INTELLIGENT PLATFORMS, INC., Charlottersville, VA (US)

(72) Inventor: Daniel Milton Alley, Earlysville, VA (US)

(73) Assignee: GE Intelligent Platforms, Inc., Charlottesville, VA (US)

(21) Appl. No.: 13/864,539

(22) Filed: Apr. 17, 2013

(51) Int. Cl. G01R 31/327

(52) U.S. Cl. CPC G01R 31/327
USPC 324/415

(57) ABSTRACT

At embedded control logic, electrical information with respect to a switching device is sensed. A decision is made as to an operation of the control logic based on the sensed information. The operation may be one or more of setting a wetting current or determining whether the electrical information is within an acceptable range.

### CROSS REFERENCE TO RELATED APPLICATIONS

Utility application entitled “Apparatus and Method for Wetting Current Measurement and Control” naming as inventor Daniel Alley, and having attorney docket number 267012 (130838);

Utility application entitled “Contact Input Apparatus Supporting Multiple Voltage Spans and Method of Operating the Same” naming as inventor Daniel Alley, and having attorney docket number 268616 (130841);

are being filed on the same date as the present application, the contents of which are incorporated herein by reference in their entireties.

### BACKGROUND OF THE INVENTION

1. Field of the Invention

The subject matter disclosed herein relates to sensing information associated with switching devices and, more specifically, to sensing various types of this information over a wide range of operating conditions and values.

2. Brief Description of the Related Art

Different types of switching devices (e.g., electrical contacts, switches, and so forth) are used in various environments. For example, a power generation plant uses a large number of electrical contacts (e.g., switches and relays). The electrical contacts in a power generation plant can be used to control a wide variety of equipment such as motors, pumps, solenoids and lights. A control system needs to monitor the electrical contacts within the power plant to determine their status in order to ensure that certain functions associated with the process are being performed. In particular, the control system determines whether the electrical contacts are on or off, or whether there is a fault near the contacts such as open field wires or shorted field wires that affect the ability of the contacts to perform their intended function.

One approach that a control system uses to monitor the status of the electrical contacts is to send an electrical voltage (e.g., a direct current voltage (DC) or an alternating current (AC) voltage) to the contacts in the field and determine whether this voltage can be detected. The voltage, which is provided to the electrical contacts for detection, is known as a wetting voltage. If the wetting voltage levels are high, galvanic isolation in the circuits is used as a safety measure while detecting the existence of voltage. Detecting the voltage is an indication that the electrical contact is on or off. A wetting current is associated with the wetting voltage.

Various problems have existed with previous approaches in monitoring contacts and other types of switching devices. For example, the contacts need to be isolated from the control system, or damage to the control system may occur. Also, the control system may need to handle a wide variety of different voltages, but previous devices could only handle voltages within narrow ranges. Previous devices have also been inflexible in the sense that they cannot be easily changed or modified without circuit changes involving setting jumpers and/or adjusting resistors or other components to account for changes in the operating environment or conditions, or received voltages. All of these problems have resulted in general dissatisfaction with previous approaches due to the need to supply many variations of the same circuit function with each set to a particular voltage and/or current.

### BRIEF DESCRIPTION OF THE INVENTION

The approaches described herein provide for a wide range of input voltage values, provide isolation, control wetting current, provide internal checking of timing and communications, and provide a command/response interface. Multiple signal voltage spans or ranges are allowed with either multiple channels provided into an analog-to-digital (A/D) converter of a microcontroller or the use of a high resolution A/D converter to allow conversion of the input voltage followed by comparison to commanded thresholds. Inclusion of timing circuits within the contact input circuit allows for signal timing to be determined for sequence of events information on the response of the contact input circuit to an external control system.

The use of an embedded A/D converter and control logic allows for either discrete parts such as microcontrollers or incorporation of the circuit within a mixed signal ASIC. Communications from the logic allows for self test operations to improve the detection of faults, improving the safety integrity level (SIL) rating on the channel.

In many of these embodiments and at embedded control logic, electrical information with respect to a switching device is sensed. A decision is made as to an operation of the control logic based on the sensed information. The operation may be one or more of setting a wetting current or determining whether the electrical information is within an acceptable range.

In some aspects, the electrical information may relate to or indicate an open switching device, a closed switching device, an open wiring, and a closed wiring. Other examples are possible.

In other aspects, the decision is associated with setting the wetting current, In other examples, a power or communications isolation with a control system. In some examples, the isolation is provided by at least one optocoupler or other form of galvanic isolation for data.

In still other examples, programming commands are received from a control system and the programming commands are effective to program the embedded control logic. In some aspects, the sensing is accomplished across multiple ranges of the electrical information. In other examples, the electrical information is a voltage at the switching device or a wetting current.

In others of these embodiments, an apparatus includes a current sink circuit and an input voltage sensing and digitizing module. The input voltage sensing and digitizing module includes embedded control logic and is coupled to the current sink circuit. The embedded control logic is configured to sense electrical information with respect to a switching device coupled to the embedded control logic, and to make a decision as to an operation of the embedded control logic based on the sensed information. The operation is one or more of setting a wetting current using the current sink circuit and determining whether the electrical information is within an acceptable range.

### BRIEF DESCRIPTION OF THE DRAWINGS

For a more complete understanding of the disclosure, reference should be made to the following detailed description and accompanying drawings wherein:

FIG. 1 comprises a block diagram of a contact input circuit according to various embodiments of the present invention;

FIG. 2 comprises a circuit diagram of a contact input circuit according to various embodiments of the present invention;

FIG. 3 comprises a circuit diagram of a contact input circuit according to various embodiments of the present invention;

FIG. 4 comprises a circuit diagram of a contact input circuit according to various embodiments of the present invention;

FIG. 5 comprises a circuit diagram of an attenuation circuit according to various embodiments of the present invention;

FIG. 6 comprises plots of various attenuation paths according to various embodiments of the present invention; and

FIG. 7 comprises a circuit diagram of a contact input circuit according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION OF THE INVENTION

The approaches described herein provide for the programmed control of contact input settings across channels of a contact, switch, or discrete input module such as found in distributed control systems (DCS) or programmable logic controller (PLC)-based systems. The use of embedded control logic within a microcontroller or application specific integrated circuit (ASIC) is shown to allow a solution that provides programmed control of wetting current and voltage thresholds.

In one advantage of the present approaches, programmable thresholds for switch state decisions are provided. In another advantage, a programmable wetting current (based on switch voltage span) is provided. Improved self-test operations for fault detection are also obtained. The possible use of mixed signal ASIC to absorb channel components is also available. The possible insertion of mixed signal ASICs within a multi-die package to absorb isolation is also provided.

In some aspects, the present approaches use an embedded microcontroller or a mixed signal ASIC within an isolated contact input circuit. A further advantage of the present approaches is that the control logic and A/D converter can be embedded within a custom mixed signal ASIC allowing the part to be optimized for this application both in channel count, packaging, parts cost, and performance.

The present approaches provide a universal input channel, reducing the variations in products as well as allowing for random combinations of switch circuits into a single module. The present approaches also provide for isolation of the contact(s) from the control system—either to avoid ground loops disturbing analog signals or to provide for voltage zone isolation. The isolation applies both to any supplied power to the circuit as well as to communications signals to/from the circuit.

In another advantage, the use of an embedded microcontroller with an internal analog-to-digital (A/D) converter and communications, local “intelligence” may be applied to control a current sink based on sensed voltage and thereby control the wetting current. The voltage sensed by the A/D converter of the microcontroller's may be used to turn off the current sink (e.g., at high voltages) or on (e.g., at lower voltages). The communications ability and functionality provided by the microcontroller may also be used to control the sink current directly from instructions received from an external control system.

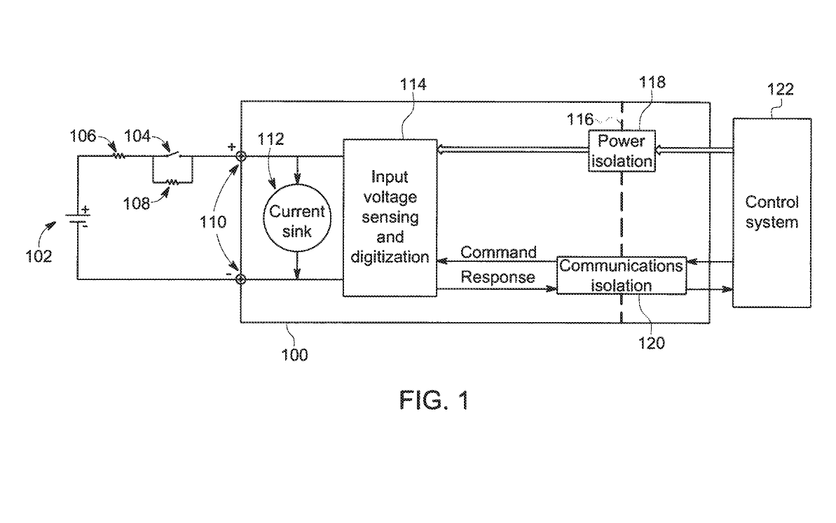

Referring now to the figures, and in particular to FIG. 1, a block diagram of a contact input circuit 100 is illustrated in accordance with various approaches. The contact input circuit 100 includes one or more inputs 110, comprising positive and negative input terminals (IN+and IN−) in this example, an input voltage sensing and digitizing module 114, as well as communications isolation circuit 120. The contact input circuit 100 is configured such that it provides information about a signal existing on the inputs 110 across an isolation barrier 116 to a control system 122 for processing thereof The control system 122 may also include any combination of processing devices that execute programmed computer software and that are capable of analyzing information received from the contact input circuit 100.

The input voltage sensing and digitizing module 114 may include an embedded control logic and this embedded control logic may be disposed in an application specific integrated circuit (ASIC), a microprocessor, or a microcontroller to mention a few examples. The input voltage sensing and digitizing module 114 senses electrical information with respect to a switching device is sensed. A decision is made as to an operation of the embedded control logic based on the sensed information. The operation may be one or more of setting a wetting current or determining whether the electrical information is within an acceptable range.

The isolation barrier 116 may represent galvanic separation such that the two sides of the isolation barrier (i.e., the input 110 side and the control system 122 side) are electrically insulated from one another to provide galvanic isolation. The isolation barrier 116 provides protection for the control system 122 from electrical characteristics and abnormalities existing on the input 110 side of the isolation barrier 116 that the control system 122 may simply be incapable of withstanding. For example, the control system 122 may be configured to operate with, for example, approximately 3.3V, approximately 5V, approximately 12V, or approximately 24V power supply and utilize corresponding small signals. However, in one example, the input 110 side of the isolation barrier 116 may be a higher-voltage circuit with operating voltages exceeding 250V, or even 500V. Further, and especially in the instance where switching devices 104 are used in power plant applications or are otherwise geographically spread apart, lighting or other phenomena may create sizeable surges on the inputs 110 exceeding hundreds or thousands of volts, which surges a control system 122 may not be capable of withstanding.

So configured, and in one example setting, the contact input circuit 100 can be utilized with a switching device 104 (e.g., an electro-mechanical switch or other switching means) such that the information provided about the signal existing at the inputs 110 can be utilized to determine various aspects or characteristics of the switching device 104 (e.g., if it is closed, open, shorted, subject to a weak connection, oxidized, etc). In such an example setting, the switching device 104 may be coupled to a power supply 102 or other power source. Various resistances associated with the switching device 104, the power supply 102, or current paths are represented generally by series resistor Rs 106 and parallel resistor Rp 108, which allow for detection of wiring faults, where the open switch voltage and closed switch voltages are different from an open wire input or a short to the supply 102.

Although only a switching device 104 application is described here, the contact input circuit 100 can be utilized in many various application settings to provide information about signals existing at the inputs 110 to the contact input circuit 100.

By at least one approach, the contact input circuit 100 may be further equipped with a current sink circuit 112. By this, the contact input circuit 100 may be configured to provide, for example, a wetting current across the switching device 104. The wetting current can be advantageously used to prevent and/or break through surface film resistance in the switching device 104, such as a layer of oxidation, which can otherwise cause the switching device 104 to remain electrically open even when it may be mechanically closed. Further applications include providing a sealing current or fritt current as may be utilized in telecommunications.

By at least another approach, the communication isolation circuit 120 can provide communications from the control system 122 to the contact input circuit 100. For example, these communications may be commands to control the current sink circuit 112 according to various requirements and/or sensed aspects of the input signal. Lastly, in another approach, the contact input circuit 100 may include a power isolation circuit 118 that is configured to provide power to the contact input circuit 100 through power transfer across the isolation barrier 116 (e.g., through the use of a transformer or by other known power transfer techniques).

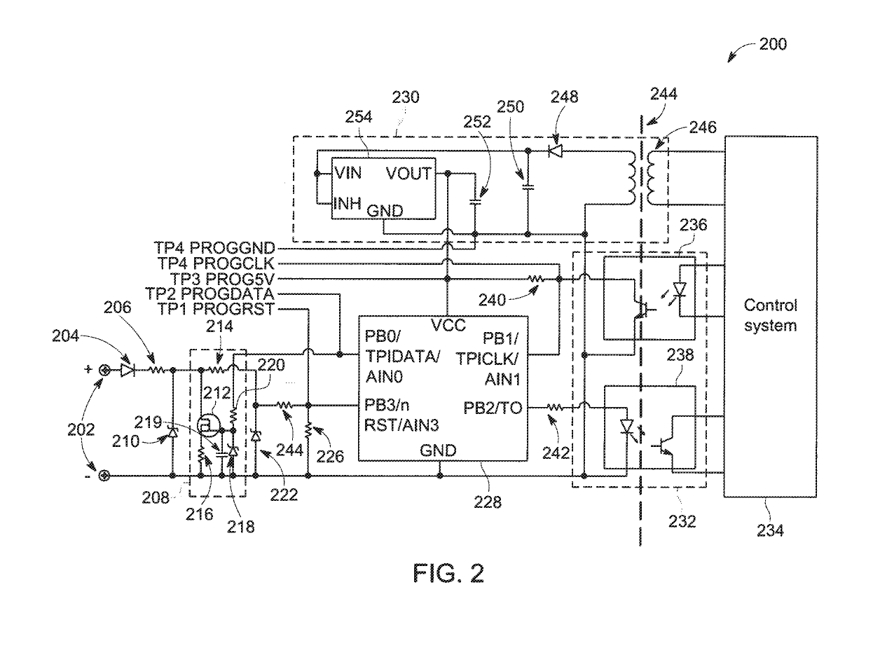

Referring now to FIG. 2, a circuit diagram of the contact input circuit 200 is illustrated. Much like the block diagram of FIG. 1, the circuit diagram includes, input contacts 202, the current sink circuit 208, an input voltage sensing and digitizing module (represented here in part as processing device 228), communications isolation circuit 232 configured to communicate with control system 234, and an optional power isolation circuit 230. Voltage enters the circuit 200 through diode 204 and resistor 206 and across protection diode 210, which operate to ensure that the circuit 200 is not damaged if the voltage inputs to the circuit 200 are accidentally reversed or an excessive voltage is input as when a lightning strike occurs on equipment that is connected to input contacts 202.

The input signal continues into a voltage attenuator circuit including resistors 214, 224, and 226 and zener diode 222. The voltage is attenuated through the voltage divider created by the set of resistors 214, 224, 226, with the output between resistors 224 and 226 being sent to an input of the processing device 228. Zener diode 222 operates as a voltage clamp to ensure the voltage into the processing device 228 stays within its input range (i.e., within approximately 3 to 4 volts for typical microcontrollers operating on a 5 volt supply).

By one approach, the processing device 228 is configured to measure the voltage of the signal received from the voltage attenuator circuit. This may be achieved by known analog-to-digital conversion techniques, or other known voltage measurement techniques, that may be internal or external to the processing device 228. By measuring this attenuated voltage, the processing device 228 then knows the voltage that exists at the input contacts 202 to the circuit 200. The processing device may be able to relate the attenuated voltage to the actual voltage at the input contacts 202 through the use of a lookup table (e.g., relating the values of the measured attenuated voltage to the input voltage) or through a simple calculation corresponding to the relation between the attenuated and actual voltages.

The processing device 228 may be further configured with one or more additional inputs that are individually or collectively configured to receive communications from external sources. For example, the processing device 228 may be able to receive commands and/or data from the control system 234 through communications isolation circuit 232 via optocoupler 236 across isolation barrier 244 to an input that may utilize a pull-up resistor 240. This input (or another input) may also be configured to receive communications from a local source (i.e., not across the isolation barrier 244) from, for example, a universal asynchronous receiver transmitter (UART), inter-integrated circuit network (I2C), or other communication port that may communicate with diagnostic and/or programming equipment, a computer, other contact input circuits, and so forth. Further still, the processing device 228 may be configured with one or more outputs that can relay commands and/or data to an external device, such as the control system 234. For example, the processing device 228 may output the output data signal through a resistor 242 and through communications isolation circuit 232 via optocoupler 238 across the isolation barrier 244 to the control circuit. The output signal may be provided to other devices as well as needed. In one example, the processing device 228 is a ATTINY 10 microcontroller manufactured by Atmel containing both an ARM 32 bit processor, internal working memory, A./D, timer, and communications interface.

In one embodiment, the processing device 228 is further configured to control a wetting current produced by the current sink circuit 208. With the knowledge of the incoming voltage, the processing device can vary the wetting current that is driven by the current sink circuit 208 according to the needs of the present conditions or voltage across the switching device 104. For example, if a low voltage exists across the switching device 104 (e.g., approximately 12V or 24V), a higher wetting current may be required to ensure enough power is provided across the switching device 104 contacts to ensure their health. However, if that same higher current were used with a higher voltage, such as 250V or 500V, that higher current would result in a much higher power than is needed across the contacts. This would also result in the need for unnecessarily large components capable of sinking the extra power that would be generated by the higher current combined with the higher voltage. Therefore, in the contact input circuit 200 as described herein, which is capable of operating with a wide range of switch voltages, it is beneficial to vary the current through the current sink circuit 208 to minimize unnecessary power dissipation and corresponding component selection. Accordingly, the processing device 228 may be configured to select an optimized wetting current for the given input voltage and further configured to control the current sink circuit 208 according to its selection. By one approach, the processing device 228 outputs a pulse train that is useable by the current sink circuit 208. Resistor 220 and capacitor 219 serve as a low pass filter, converting the pulse train from 228 into a DC voltage setting to set the gate voltage at transistor 212.

The current sink circuit 208 includes a transistor 212 (shown here as an N-channel MOSFET, though other transistor types may be equally as suitable) with its drain connected to the high voltage input and its source connected through a resistor 216 to ground. This path provides a wetting current across the input contacts 202 and thus across the switching device 104. By one approach, the current sink circuit 208 receives a pulse train from the processing device 228 into input resistor 220. The pulse train is then low pass filtered by a zener diode 218 and a capacitor 219 in parallel between the gate of the transistor 212 and ground. By this, the low pass filter will establish a DC voltage at the gate of the transistor 212 commensurate with the duty cycle of the wetting current pulse train from the processing device 228. This DC voltage will resultantly set the wetting current through the transistor 212. Thus, the wetting current can be varied as needed via local control directly within the same input contact circuit 200.

Optionally, the processing device 228 and other components of the input contact circuit 200 may he powered from power sourced from the control system 234 (or another source across the isolation barrier 244. In one example, a transformer 246 is provided with current in its primary side winding from the control system 234, which power is then transferred across the isolation barrier 244 to the secondary winding of the transformer 246. By one approach, and in an attempt to minimize a foot print as well as cost, the transformer 246 may be a planar transformer comprised of two sets of loops (i.e., the primary and secondary windings) within a circuit board. Current from the secondary winding of the transformer 246 travels through rectifying diode 248 and across filtering capacitor 250, which operates to provide a filtered input into voltage regulator 254. Voltage regulator 254 outputs a positive voltage supply for the circuit 200, which can be further filtered by filtering capacitor 252. This operating voltage can then be used by the processing device 228 as well as other components requiring operating voltages.

As shown here, by one approach, the processing device 228 may be as small as a 6-pin device, allowing for an input to sense the incoming voltage, one to control the current sink circuit 208, and two for two-way data communication (with two pins for power and ground). Thus, the cost, complexity, and footprint of the processing device 228 can be minimized by this approach.

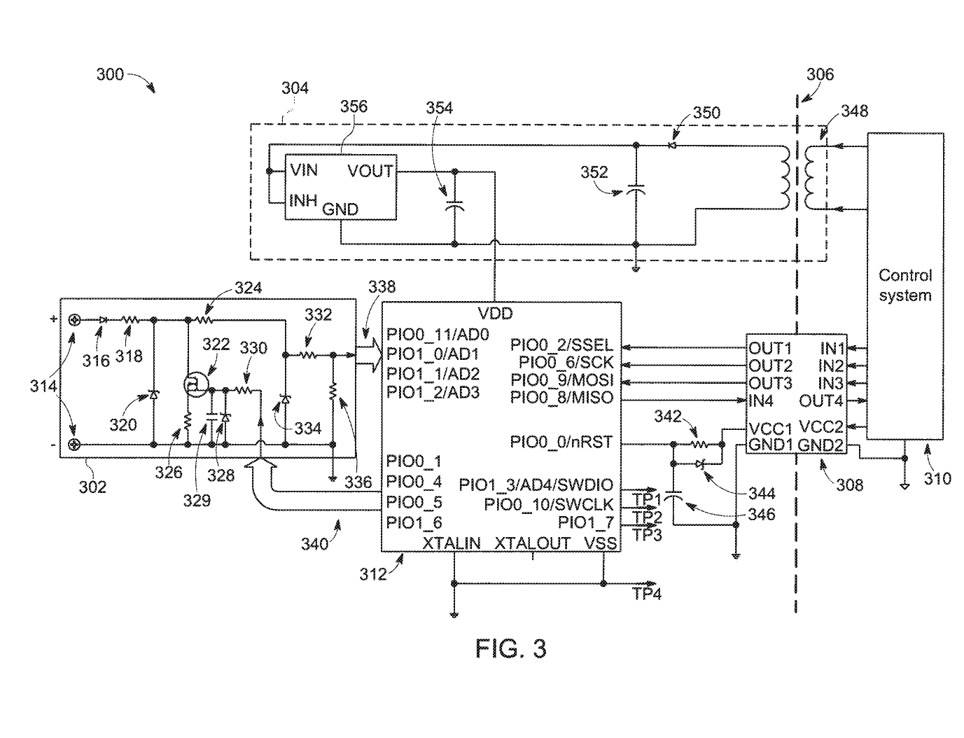

Referring next to FIG. 3, another contact input circuit 300 is described. Much like the approach described with respect to FIG. 2 above, this approach includes a processing device 312, a communication isolation circuit 308 (here shown as a single component capable of communicating via multiple paths between the processing device and the control system, though a plurality of individual components may also be suitable) that bridges an isolation barrier 306 to a control system 310, as well as a power isolation circuit 304. The approach of FIG. 3, however, utilizes a much larger processing device 312 than the example 6-pin processing device 228 of FIG. 2. In one example, the processing device 312 is a LPC 1111 manufactured by N×P, containing the same ARM 32 bit processor and associated peripherals while increasing the pin count to increase available analog/digital (A/D) and digital input/output (I/O) pins. The increased size of the processing device 312 allows for additional inputs and outputs. Accordingly, the teachings of FIG. 2 can be expanded and repeated across a plurality of contact input channels 302 to reduce otherwise redundant features or components. So, although complexity, cost, and size of the processing device 312 may be increased, these increases may be amortized over a plurality of input channels 302, thereby reducing the overall cost and size per channel.

The illustrated contact input circuit 300 represents a single contact input channel of a plurality of identical (or nearly identical) input channels 302 (shown here as four different input channels 302). Each individual input channel 302 may be configured to be coupled to a different individual switching device 104 to provide monitoring thereof as well as well as provide a wetting current.

Each channel 302 is identical or similar to the singular input channel of FIG. 2, and includes input terminals 314, and diode 316, resistor 318, and protection diode 320, which operate to ensure that the contact input circuit 300 is not damaged if the voltage inputs to the contact input circuit 300 are accidentally reversed. An input signal travels through these protective measures and continues into a voltage attenuator circuit including resistors 324, 332, and 336, and zener clamp diode 334. The voltage is attenuated through the voltage divider created by the set of resistors 324, 332, and 336, with the output existing between resistors 332 and 336. Zener diode 222 operates as a voltage clamp to ensure the voltage into the processing device 228 stays within an appropriate input range (e.g., within 3 to 4 volts) for the processing device 312. Each contact input channel 302 will output 338 its attenuated voltage to a separate input of the processing device 312, such as an analog-to-digital converting input, or the like. By this, the processing device can receive readings from multiple different input channels corresponding to different switching devices 104.

Each input channel 302 is also configured with a current sink circuit, such as current sink circuit 208 from FIG. 2. Each current sink circuit includes a transistor 322 (shown here as an N-channel MOSFET, though other transistor types may be equally as suitable) with its drain connected to the high voltage input and its source connected through a resistor 326 to ground. This path provides a wetting current across the input terminals 314 of each channel 302 and thus across each individual switching device 104. Each of the current sink circuits of each of the input channels 302 is coupled 340 to an output pin of the processing device 312 so that they may be controlled independently according to their individual needs. By one approach, each current sink circuit receives a pulse train from the processing device 312 into input resistor 330. The pulse train is then low pass filtered by a Zener diode 328 and a capacitor 329 in parallel between the gate of the transistor 322 and ground. By this, the low pass filter will establish a DC voltage at the gate of the transistor 322 commensurate with the duty cycle of the wetting current pulse train from the processing device 312. This DC voltage will resultantly set the wetting current through the transistor 322. Thus, the wetting current can be varied as needed via local control directly within the same contact input circuit 300 for multiple different input contact channels 310 using the same processing device 312.

In some aspects, the processing device 312 may utilize a reset circuit to detect and recover from supply fluctuations and initial power up. Resistor 342, capacitor 346, and Schottky diode 344 may be used to provide the timing for the reset circuit. A watchdog timer within the processing device 312 may be used to further improve recovery from computing malfunctions, with the example LPC 1111 containing a watchdog timer internally.

As with FIG. 2, optionally, the processing device 312 and other components of the contact input circuit 300 may be powered from power sourced from the control system 310 (or another source across the isolation barrier 306. In one example, a transformer 348 (e.g., a planar transformer) is provided with current in its primary side winding from the control system 310, which power is then transferred across the isolation barrier 306 to the secondary winding of the transformer 348. Current from the secondary winding of the transformer 348 travels through rectifying diode 350 and across filtering capacitor 352, which operates to provide a filtered input into voltage regulator 356. Voltage regulator 356 outputs a positive voltage supply for the contact input circuit 300, which can be further filtered by filtering capacitor 354. This operating voltage can then be used by the processing device 312 as well as other components requiring operating voltages.

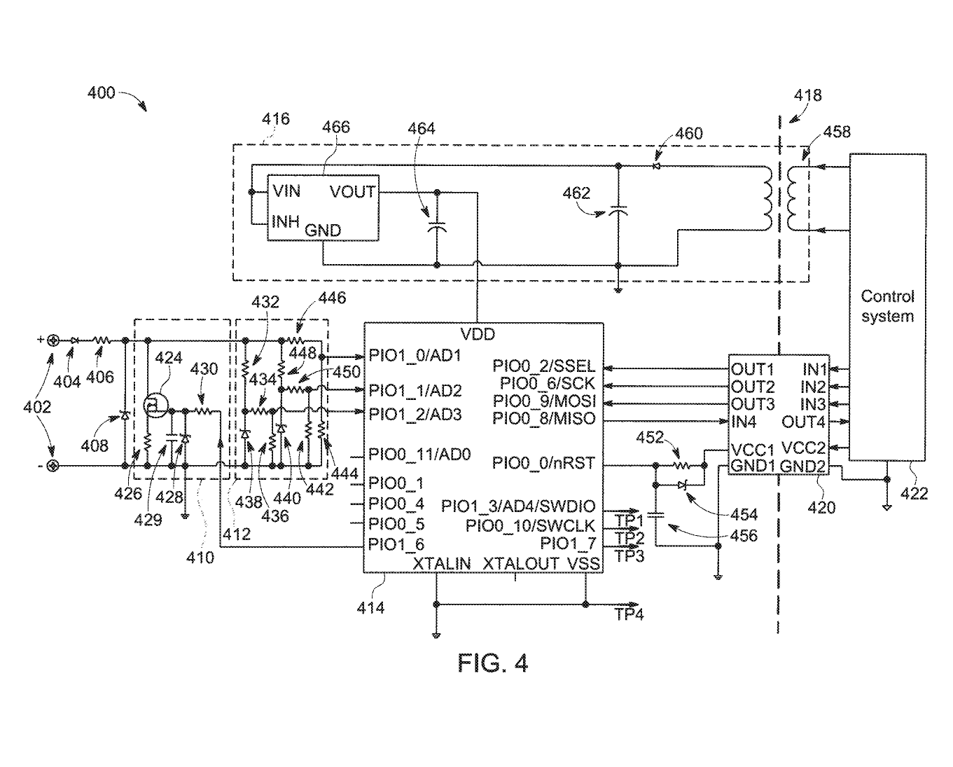

Turning now to FIG. 4, another contact input circuit 400 is described. FIG. 4 depicts the same or similar larger processing device 414 as FIG. 3, along with the watchdog timer (including resistor 452, Schottky diode 454, and capacitor 456), communication isolation circuit 420 which bridges the isolation barrier 418 to allow communication between the processing device 414 and the control system 422. In one example, the processing device 414 is a LPC 1111 manufactured by N×P as shown earlier in FIG. 3. FIG. 4 also illustrates the power isolation circuit 416 including transformer 458, rectifying diode 460, filtering capacitor 462, voltage regulator 466, and output voltage filtering capacitor 464. Further, FIG. 4 shows the input terminals 402 coupled to the input protection components, including diode 404, resistor 406, and protection diode 408, as well as the current sink circuit 410 identical or similar to those described in reference to FIGS. 2 and 3. The current sink circuit includes the transistor 424, drain resistor 426, input resistor 430, and input low pass filter comprising Zener diode 428 and filtering capacitor 429 and is configured, by one approach, to receive and filter a wetting current pulse train from an output of the processing device 414. These above components of FIG. 4 may all be configured and arranged as was discussed with respect to FIGS. 2 and 3.

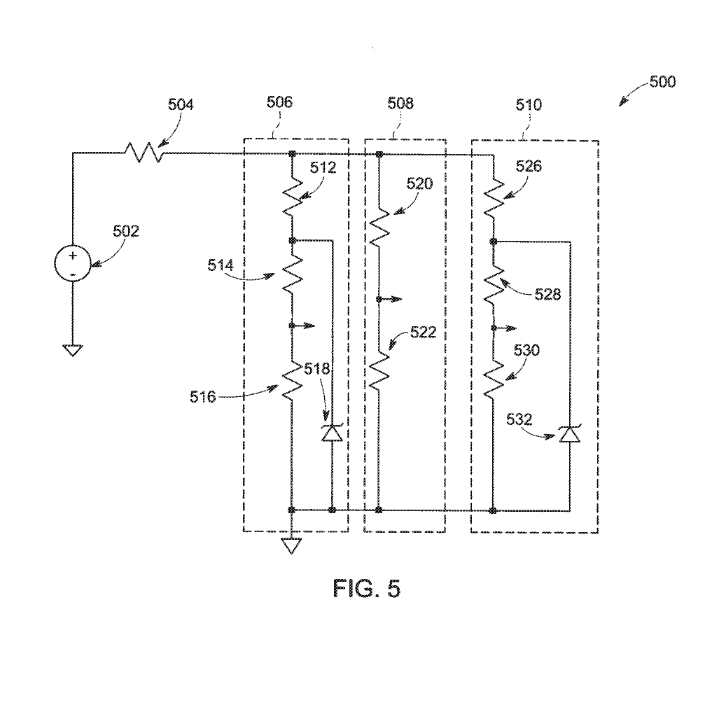

The attenuation circuit 412 portion of the contact input circuit is altered in FIG. 4, however, to utilize the multiple analog-to-digital converting input pins of a larger processing device 414. Unlike FIGS. 2 and 3, the attenuation circuit 412 is configured to output multiple different attenuated voltages with varying gains to better accommodate sensing of the wide range of input voltages. The attenuation circuit 412 includes, by one approach, resistors 432, 434, 436, 442, 444, 446, 448, and 450, as well as Zener clamp diodes 438 and 440. The specific arrangement and functionality of these components is described with respect to FIG. 5 below.

FIG. 5 illustrates an attenuation circuit 500 representative of the attenuation circuit 412 of FIG. 4. FIG. 5 includes a voltage source 502, which is a simulated voltage as may be present on the input terminals 402 of the contact input circuit 400 of FIG. 4, as well as input resistor 504, which correspond to input resistor 406 of FIG. 4. The attenuation circuit includes three different attenuation paths 506, 508, 510, each corresponding to a different gain and maximum input voltage. Each attenuation path comprises a resistor voltage divider circuit, and may include a voltage clamp Zener diode to prevent the output from exceeding an allowable input into the processing device 414.

Attenuation path 506 may correspond to, for example, a maximum voltage of 48 volts (with a certain tolerance by some approaches, for example, including about 10%). Resistors 512, 514, and 516 are selected so that a voltage at or near the higher end of the allowable input into the processing device 414 (for example, 5V) is achieved when the input voltage is at around 48V. This creates a higher gain than the other attenuation paths 508 and 510. Zener clamp diode 518 is provided to ensure that the output of this first attenuation path 506 (existing between resistors 514 and 516) does not exceed the maximum output (e.g., approximately 5V) even when the input voltage exceeds the 48V point.

Attenuation path 510 may correspond to, for example, a maximum voltage of 150V. Resistors 526, 528, and 530 are selected so that a voltage at or near the higher end of the allowable input into the processing device 414 (for example, 5V) is achieved when the input voltage is at around 150V. This creates a lower gain than attenuation path 506, but higher than attenuation path 510. Zener clamp diode 532 is provided to ensure that the output of this second attenuation path 510 (existing between resistors 528 and 530) does not exceed the maximum output (e.g., 5V) even when the input voltage exceeds the 150V point.

Finally, attenuation path 508 may correspond to, for example, a maximum voltage of 250V. Resistors 520 and 522 are selected so that a voltage at or near the higher end of the allowable input into the processing device 414 (for example, 5V) is achieved when the input voltage is at around 250V. This creates a lower gain than attenuation paths 506 and 510. This attenuation path may not require a Zener clamp diode as the input voltage may not exceed a maximum input 250V in this example and thus, the output (between resistors 520 and 522) will not exceed the maximum for the processing device 414 (though other maximum inputs are possible by other approaches, including but not limited to 500V, wherein a 250V maximum attenuation path 508 would preferably include a Zener clamp diode).

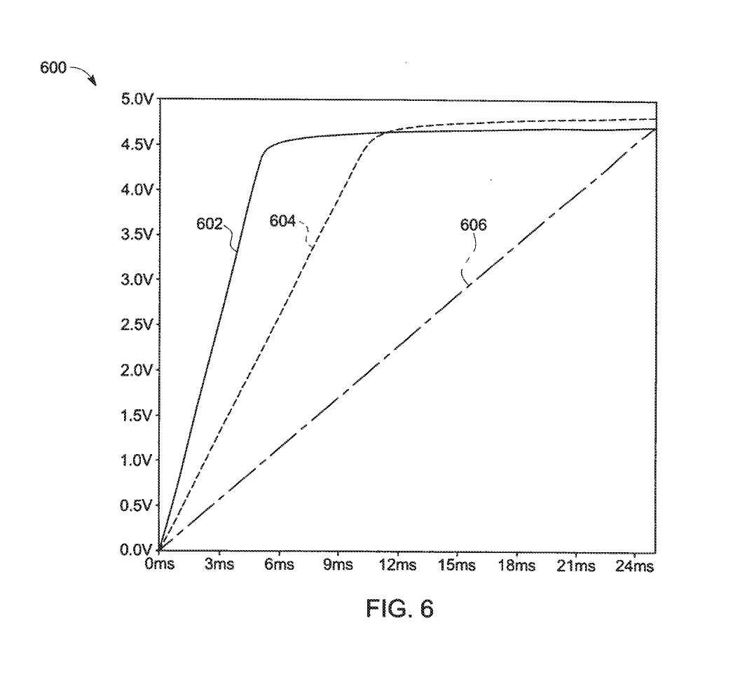

Turning to FIG. 6, the various gains of the various attenuation paths 506, 508, 510 of FIG. 5 are illustrated in graph 600 by one example. The x-axis represents time as a voltage on the input (i.e., simulated voltage source 502 in FIG. 5) is swept linearly from 0V to 250V (and thus indirectly represents input voltage). The y-axis represents the output voltage that is fed to the processing device 414. Curve 602 represents the output of the first attenuation path 506 (with an example maximum input voltage of 48V), curve 604 represents the output of the second attenuation path 510 (with an example maximum input voltage of 150V), and curve 606 represents the output of the third attenuation path 508 (with an example maximum input voltage of 250V). As can be seen from the graph 600, as the voltage input remains lower (e.g., from 0-48V), all three attenuation paths 506, 508, 510 are active and will provide usable output readings to the processing device 414 (corresponding to the sloped portions of each curve 602, 604, 606). As the input voltage increases beyond the example 48V, the first attenuation path 506 will become clamped near 5V, and will be otherwise unusable to provide an accurate reading corresponding to the input voltage. However, the second and third attenuation paths 510, 508, will remain active and usable for readings corresponding to the input voltage. As the input voltage increases more and surpasses the example 150V maximum of the second attenuation path 510, the second attenuation path 510 will clamp to near 5V, leaving the third attenuation path 508 as the only active path.

By this, a varying degree of precision can be achieved according to the input voltage range. For example, and with continuing reference to FIG. 6, if the input voltage was very low, for example, near 12V, the output voltage from attenuation path 508 (with a maximum of 250V and representing the entire input range in this example) would output a very small voltage. However, the second attenuation path 510 would output a larger output voltage, while the first attenuation path 506 would output the largest output voltage as it is the most sensitive. This increased sensitivity to lower input voltages allows for enhanced resolution when measuring these lower input voltage (that is, up until the respective attenuation path maxes out). Allowing for this better resolution allows for less sophisticated or accurate digital-to-analog converters to be used at the input to the processing device 414. Further, the redundant measurements created by the varying attenuation paths 506, 508, 510 allow for the processing device 414 to check sensed values against each other to ensure that the device is operating properly. Thus, the increased size of the processing device 414 can be utilized by providing these multiple voltage input readings to multiple inputs of the processing device 414 to provide more accurate voltage input readings.

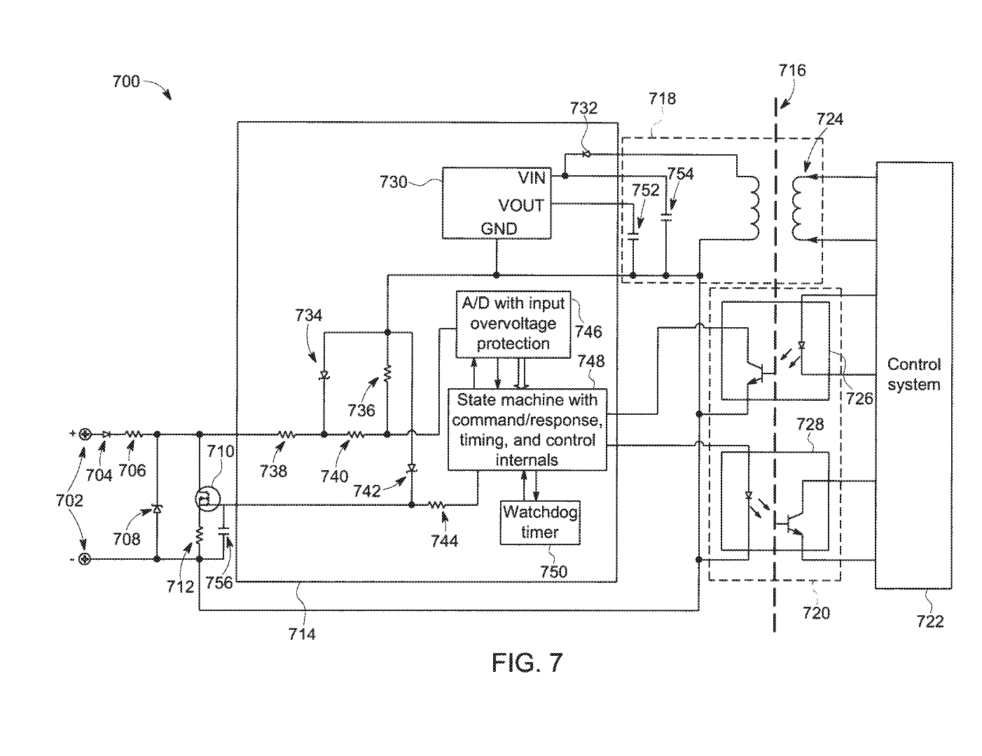

Referring now to FIG. 7, another contact input circuit 700 is described. FIG. 7 shows various circuitry and components of various previously discussed approaches embedded into a single component (i.e., into an ASIC, integrated circuit, or the like). The single component 714, by some approaches, may include a state machine 748 (which may include many command and response capabilities, timing, and control), a watchdog timer 750, and one or more analog-to-digital converters (ADC) 746 (that may include overvoltage protection, such as Zener clamping diodes or the like). The single component 714 may also include an internal voltage regulator 730 that may be configured to receive supply voltage, for example, through a rectifying diode 732. The voltage regulator 730 may be configured to operate with various external voltage supply components 718, including an external transformer 724 that bridges the isolation barrier 716 to the control system 722, as well as external power filtering capacitors 752 and 754.

By one approach, and as discussed above, input voltage across the input contacts 702 enters the contact input circuit 700 through a protection circuit including diode 704, resistor 706, and protection Zener diode 708. This input voltage is then fed into the input of the single component 714. The single component 714 may also include a voltage attenuation circuit including a resistor voltage divider circuit comprised of series resistors 738, 740, and 736 that receives the input voltage and outputs an attenuated voltage on a node between resistors 740 and 736. A Zener clamp diode 734 may also be included from ground to a node between series resistors 738 and 740, ensuring the input voltage into the ADC does not exceed its maximum allowable input. The voltage attenuator circuit is configured to receive input voltage and provide a scaled output voltage to the ADC 746. The ADC 746 then communicates with the state machine 748 to provide readings of the scaled input voltage.

As discussed above with respect to various processing devices, the state machine 748 is configured by some approaches to determine a wetting current based on the sensed input voltage. The state machine 748 may output a pulse train that is fed across a Zener clamp diode 742 and a low pass filtering capacitor 756 and output from the single component 714 to the gate of a FET 710, as discussed above. The filtered wetting current pulse train will create a DC voltage on the input to the FET 710, which then controls the current therethrough and through resistor 712. The FET 710 is preferably external to the single component 714 as it will be capable of sinking relatively higher amounts of current than are appropriate for a single component 714.

Additionally, as discussed above in reference to other embodiments, the single component 714 may be capable of communicating with external components such as the control system 722 through a communication isolation circuit 720 across isolation Wilier 716. The state machine 748 may include one or more communication inputs that may be coupled to the control system 722 across the isolation barrier 716 through one or more optocouplers 726. Similarly, the state machine 748 may include one or more communication outputs that may communicate data to the control system 722 across the isolation barrier 716 through one or more other optocouplers 728.

By using the single component 714, the features and functionality as described with respect to previous figures discussed herein may be incorporated into a single, low-cost component, thus reducing the size, complexity, and cost of the contact input circuit 700.

As has been described herein, contact input circuits are provided that are capable of receiving a wide range of input voltages and are correspondingly capable of varying a wetting current through the contacts of a switch. The power dissipated by the wetting current is optimized for various input currents. Systems that are not capable of varying the wetting current must set the wetting current high enough to account for the lowest input voltage in order to maintain universality. Such a design requires large and robust components capable of withstanding the power dissipation that is produced from combining the high current required with low voltage inputs with a high voltage input (e.g., approximately 250V or 500V). Thus, by varying the wetting current according to the input voltage as described herein, universality can be maintained while reducing the size or robustness of various components, therefore reducing cost and size of the contact input circuit. Further, by including the capability to control the wetting current locally within the contact input circuit, a contact input circuit is provided that does not rely exclusively on a control system for control of the wetting current, thus increasing the number of systems which the contact input control system is compatible with, as well as offloading the processing from the control system.

It will be appreciated that the various examples described herein use various components (e.g., resistors and capacitors) that have certain values. Example values are shown in the figures for many of these components. However, if not shown, these values will be understood or easily obtainable by those skilled in the art and, consequently, are not mentioned here.

It will be appreciated by those skilled in the art that modifications to the foregoing embodiments may be made in various aspects. Other variations clearly would also work, and are within the scope and spirit of the invention. The present invention is set forth with particularity in the appended claims. It is deemed that the spirit and scope of that invention encompasses such modifications and alterations to the embodiments herein as would be apparent to one of ordinary skill in the art and familiar with the teachings of the present application.

What is claimed is:

1. A method of sensing information and measuring wetting current, the method comprising:
at embedded control logic:
sensing electrical information with respect to a switching device;
making a decision as to an operation of the embedded control logic based on the sensed electrical information, wherein the operation is at least one operation selected from the group consisting of: setting a wetting current and determining whether the sensed electrical information is within an acceptable range.

2. The method of claim 1 wherein the electrical information is information selected from the group consisting of an open switching device, a closed switching device, an open wiring, and a closed wiring.

3. The method of claim 1 wherein the decision is associated with setting the wetting current.

4. The method of claim 1 further comprising providing a power or communications isolation with a control system.

5. The method of claim 4 wherein the isolation is provided by at least one optocoupler.

6. The method of claim 1 further comprising receiving programming commands from a control system, the programming commands effective to program the embedded control logic.

7. The method of claim 1 wherein the sensing is accomplished across multiple ranges of the electrical information.

8. The method of claim 1 wherein the electrical information comprises a voltage at the switching device or a wetting current.

9. An apparatus that is configured to sense information, the apparatus comprising:
a current sink circuit;
an input voltage sensing and digitizing module that includes embedded control logic and that is coupled to the current sink circuit, the embedded control logic being configured to sense electrical information with respect to a switching device coupled to the embedded control logic, and to make a decision as to an operation of the embedded control logic based on the sensed electrical information;
wherein the operation is at least one operation selected from the group consisting of:
setting a wetting current using the current sink circuit and determining whether the sensed electrical information is within an acceptable range.

10. The apparatus of claim 9 wherein the embedded control logic comprises a device selected from the group consisting of a microprocessor and an application specific integrated circuit (ASIC).

11. The apparatus of claim 9 wherein the electrical information is information selected from the group consisting of an open switching device, a closed switching device, an open wiring, and a closed wiring.

12. The apparatus of claim 9 wherein the decision comprises setting or controlling the wetting current.

13. The apparatus of claim 9 further comprising isolation circuitry and wherein a power or communications isolation is provided between the embedded control logic and a control system by the isolation circuitry.

14. The apparatus of claim 13 wherein the isolation circuitry comprises at least one optocoupler to provide the power or communications isolation.

15. The apparatus of claim 9 wherein the embedded control logic is configured to receive programming commands from a control system.

16. The apparatus of claim 9 wherein the sensing is accomplished across multiple ranges of the electrical information, the electrical information related to a voltage across the switching device or a wetting current.
